(19) United States
(12) Patent Application Publication
(10) Pub. No.: US 2024/0413227 A1
(43) Pub. Date: Dec. 12, 2024

(54) BIPOLAR TRANSISTOR

(71) Applicant: Nippon Telegraph and Telephone Corporation, Tokyo (JP)

(72) Inventors: Takuya Hoshi, Tokyo (JP); Yuta Shiratori, Tokyo (JP); Hiroki Sugiyama, Tokyo (JP); Yuki Yoshiya, Tokyo (JP)

(21) Appl. No.: 18/699,163

(22) PCT Filed: Nov. 16, 2021
(86) PCT No.: PCT/JP2021/042008

§ 371 Date: Apr. 5, 2024

(51) Int. Cl. H01L 29/737; H01L 29/20; H01L 29/417; H01L 29/66

(52) U.S. Cl. CPC H01L 29/737; H01L 29/2003; H01L 29/41708; H01L 29/66318

(57) ABSTRACT

A hetero-junction bipolar transistor includes an n-type collector layer made of InGaN, a base layer formed on the collector layer and made of GaN, and an emitter layer formed on the base layer and made of a nitride semiconductor containing Al, in which the collector layer, the base layer, and the emitter layer are formed in a state in which the principal surface is a group V polar plane. The base electrode can be formed in contact with the upper part of the base layer around the emitter layer formed in a mesa shape.

### CROSS-REFERENCE TO RELATED APPLICATIONS

This application is a national phase entry of PCT Application No. PCT/JP2021/042008, filed on Nov. 16, 2021, which application is hereby incorporated herein by reference.

### TECHNICAL FIELD

The present invention relates to a bipolar transistor.

### BACKGROUND

A nitride semiconductor has a large band gap, and therefore is promising as a high-speed and high-withstand-voltage electronic device material. A high-electron-mobility transistor utilizing a high-density sheet carrier generated by polarization of AlGaN/GaN has been studied actively by many research institutions, and has already been put into practical use as an amplification transistor for a communication amplifier and a high-efficiency power device.

A hetero-junction bipolar transistor (HBT) has a device structure capable of achieving a high withstand voltage, using a high-withstand-voltage material for a collector layer, and achieving both high-speed performance and high-withstand-voltage performance. In Group III-V compound semiconductors using InP or GaAs as a substrate material and a Group IV material using SiGe as a base layer, there are many reports that a cut-off frequency, a maximum oscillation frequency, and a high withstand voltage of several hundred GHz are compatible in the HBT structure.

It is expected that, even with a GaN-based material as a wide gap material, by realizing an HBT using this material, a transistor with an even higher withstand voltage and higher speed than conventional Group III-V compound semiconductors can be realized.

However, it is difficult to make a nitride semiconductor such as GaN into a p-type at a high concentration as will be described below. First, in the nitride semiconductor, ionization energy of the impurity functioning as an acceptor is very great. In addition, the nitride semiconductor is grown by a general growth technique such as a MOCVD, but there is an essential problem that a doped dopant (Mg, Zn, or the like) is inactivated by H (hydrogen) contained in a carrier gas or a raw material at the time of p-type doping, and the hole concentration cannot be increased.

In order to increase the HBT speed, although it is necessary to obtain a high concentration, a low resistance, and a low contact resistance of both the n-type and the p-type, as described above, it is very difficult to achieve high speed in the HBT using the nitride semiconductor with which it is difficult to achieve a high concentration of p-type.

In the semiconductor device using the nitride semiconductor such as GaN, one technique for obtaining a high hole concentration has been devised for manufacturing a device with an N polar plane as a principal plane orientation. The nitride semiconductor is a material having polarization in a c-axis direction, and generally crystal growth is carried out in the (+c-axis direction) plane orientation called a Group III polar plane to manufacture a device. In the case of a Group III polar plane, when AlGaN is grown on GaN, the band is bent by an electric field due to a difference in magnitude of spontaneous polarization between materials and a polarization electric field generated by distortion generated in an AlGaN layer, and a two-dimensional electron gas is generated at an interface between AlGaN and GaN. A GaN channel HEMT structure has been realized by utilizing this structure, and a high-frequency device using this structure has already been put into practical use.

On the other hand, in the configuration in which the principal surface is an N polar (Group V polarity) surface, the Group III polarity surface is reversed. In this case, the direction of the electric field generated by polarization is reversed from the case of the Group III polar plane. For example, in a case where AlGaN is formed on GaN with an N polar plane as a principal plane orientation, a two-dimensional hole gas is generated by a polarization electric field at an AlGaN/GaN interface (see NPL 1). In the HBT using GaN having the N polar plane as the principal plane orientation, the above-mentioned two-dimensional hole gas is utilized to overcome the problem related to the p-type doping control.

However, in the HBT that utilizes a two-dimensional hole gas formed using an N polar plane, there is a problem to be overcome with respect to ohmic contact between the base layer and the base electrode. In the HBT structure having an N polar plane as a principal plane orientation, a technique for increasing the concentration of a p-base layer 304a by obtaining a two-dimensional hole gas 321 at an interface between an emitter layer 305 made of AlGaN and the p-base layer 304a made of p-type GaN is used as shown in FIG. 7A.

The HBT includes a buffer layer 307 formed on a substrate 301, a sub-collector layer 302 formed on the buffer layer 307 and made of an n-type nitride semiconductor, a collector layer 303 formed on the sub-collector layer 302 and made of n-type GaN, a p-base layer 304a formed on the collector layer 303 and made of p-type GaN, a base layer 304b formed on the p-base layer 304a and made of undoped GaN, an emitter layer 305 formed on the base layer 304b, and an emitter cap layer 306 formed on the emitter layer 305 and made of an n-type nitride semiconductor.

The HBT has an emitter electrode 311 formed on the emitter cap layer 306, a base electrode 312 formed on the base layer lateral to the emitter layer 305, and a collector electrode 313 connected to the sub-collector layer 302. In the structure of the emitter top shown in FIG. 7A, it is necessary to form ohmic contacts between each electrode made of metal, the emitter cap layer 306, the base layer 304b, and the sub-collector layer 302 from the upper surface side (surface side) of the device.

In the HBT, since the base layer is highly concentrated by the two-dimensional hole gas 321, it is important that the emitter layer 305 also be immediately under the base electrode 312, but the emitter layer 305 made of AlGaN has a high resistance. Therefore, as shown in FIG. 7A, when the base electrode 312 is formed immediately above the emitter layer 305, ohmic contact resistance becomes high. In order to obtain good ohmic contact between the base layer 304b and the base electrode 312, it is necessary to take measures such as partially removing the emitter layer 305b immediately below the base electrode 312 by etching to make it thinner, as shown in FIG. 7B.

However, as shown in FIG. 7C, if the emitter layer 305c is completely removed, the concentration of the two-dimensional hole gas 321 is extremely reduced (eliminated), and therefore etching of the emitter layer 305c for forming the base electrode requires very high controllability.

### CITATION LIST

### Non Patent Literature

NPL 1—“Emitter top type GaN HBT having two-dimensional hole gas produced by epitaxial lift-off method,” 80th Japan Society of Applied Physics Autumn Meeting lecture, 21 a-E301-5 13.7, 2019.

### SUMMARY

### Technical Problem

As described above, in the GaN-based HBT structure having the N polarity as the principal plane orientation, there is a problem that it is difficult to obtain good ohmic contact between the base layer and the base electrode. Although the emitter layer plays an important role for generating a two-dimensional hole gas, since it has a high resistance, the ohmic resistance at the time of electrode formation is increased. However, if the emitter layer immediately below the base electrode is completely removed, the two-dimensional hole gas immediately below the emitter is lost, causing an increase in the base resistance and an increase in the base contact resistance.

Embodiments of the present invention have been made to solve the above-mentioned problems, and an object of embodiments of the present invention is to obtain good ohmic contact between a base layer and a base electrode in a GaN-based bipolar transistor structure having N polarity as a principal plane orientation.

### Solution to Problem

A bipolar transistor according to embodiments of the present invention includes a sub-collector layer which is formed on a substrate and made of an n-type nitride semiconductor; an n-type collector layer which is formed on the sub-collector layer and made of InGaN; a base layer which is formed on the collector layer and made of GaN; a mesa-shaped emitter layer which is made of a nitride semiconductor containing Al formed on the base layer; an emitter cap layer which is formed on the emitter layer and made of an n-type nitride semiconductor; an emitter electrode formed on the emitter cap layer; a base electrode which is formed on the base layer beside the emitter layer and is ohmically connected to the base layer; a collector electrode connected to the sub-collector layer; and a two-dimensional hole gas which is formed in each of the base layer near an interface between the base layer and the collector layer and the collector layer near an interface between the collector layer and the base layer, in which the sub-collector layer, the collector layer, the base layer, the emitter layer, and the emitter cap layer are formed on the substrate with principal surfaces being Group V polar planes.

### Advantageous Effects of Embodiments of the Invention

As described above, according to embodiments of the present invention, since the base layer made of GaN is formed on the collector layer made of InGaN with each principal surface being a Group V polar plane, and an emitter layer made of the nitride semiconductor containing Al is formed on the base layer, good ohmic contact between the base layer and the base electrode can be obtained in a GaN-based bipolar transistor structure having N polarity as a principal plane orientation.

### BRIEF DESCRIPTION OF THE DRAWINGS

FIG. 1 is a cross-sectional view showing a configuration of a bipolar transistor according to an embodiment of the present invention.

FIG. 2A is a band diagram showing a band state of the bipolar transistor according to an embodiment of the present invention.

FIG. 2B is a band diagram showing a band state of a bipolar transistor of the related art.

FIG. 3 is a band diagram showing the band state of the bipolar transistor according to an embodiment of the present invention.

FIG. 4 is a characteristic diagram showing results obtained by performing calculation of sheet carrier density of the bipolar transistor according to an embodiment of the present invention.

FIG. 5 is a cross-sectional view showing the configuration of another bipolar transistor according to an embodiment of the present invention.

FIG. 6 is a band diagram showing a band state of another bipolar transistor according to an embodiment of the present invention.

FIG. 7A is a cross-sectional view showing a GaN-based HBT structure with N-polarity as a principal plane orientation of the related art.

FIG. 7B is a cross-sectional view showing a GaN-based HBT structure with N-polarity as the principal plane orientation of the related art.

FIG. 7C is a cross-sectional view showing a GaN-based HBT structure with N-polarity as the principal plane orientation of the related art.

### DETAILED DESCRIPTION OF ILLUSTRATIVE EMBODIMENTS

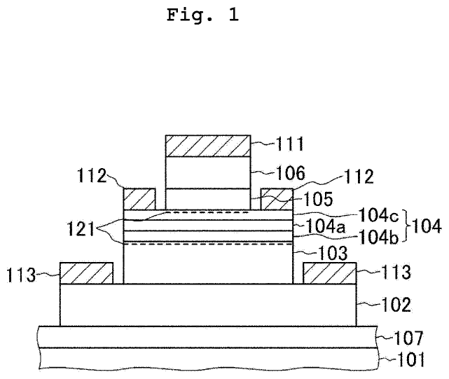

Hereinafter, a bipolar transistor (hetero-junction bipolar transistor: HBT) according to an embodiment of the present invention will be described with reference to FIG. 1. The HBT first includes a sub-collector layer 102 formed on a substrate 101, and a collector layer 103 formed on the sub-collector layer 102. In this example, the sub-collector layer 102 is formed on a buffer layer 107.

The substrate 101 is used for forming a nitride semiconductor device, and the material of the substrate 101 is selected so that the N polar plane is set to the principal plane orientation (a state in which the principal surface is set to the group V polar plane). For example, as the substrate 101, sapphire, a C-plane SiC substrate, an N polar GaN, an N polar AlN substrate, or the like can be used.

As the buffer layer 107, when the substrate 101 is a sapphire substrate, a nitride layer on the substrate surface formed by subjecting the surface of the substrate 101 to high-temperature heat treatment under a raw material gas atmosphere such as ammonia can be set as the buffer layer 107. A nitride semiconductor having an N polar plane as a principal plane orientation can be crystal-grown on the buffer layer 107 formed by nitriding. On the other hand, when a GaN single crystal substrate or an AlN single crystal substrate having an N polar plane as a principal plane orientation is used as the substrate 101, a nitride semiconductor having an N polar plane as a principal plane orientation can be crystal-grown without using a special buffer layer.

The sub-collector layer 102 can be made of a highly n-type doped nitride semiconductor (GaN or InGaN). For example, the sub-collector layer 102 can be made of n-type doped GaN with a high concentration. Since the sub-collector layer 102 also functions as a contact layer for realizing ohmic contact with a collector electrode 113 to be described later, the doping concentration is set to a relatively high concentration (for example, 5×10¹⁸ cm⁻³ or more). Further, the sub-collector layer 102 grows relatively thick in a range that does not affect the device characteristics. For example, it is desirable that the thickness of the sub-collector layer 102 be set to at least 1 μm or more to function as a buffer layer for improving the crystal quality.

The collector layer 103 is made of InₓGa₁₋ₓN (0<x<1) in which the In composition is always set to be greater than 0. The doping concentration for making InGaN constituting the collector layer 103 n-type is set to be smaller than that of the sub-collector layer 102. For example, the collector layer 103 can be made of n-type InGaN having an n-type impurity concentration of about 10¹⁷ cm⁻³. As will be described later, the collector layer 103 can be made of InGaN with an In composition of 0.05 or more. The thickness of the collector layer 103 can be about 50 nm.

The HBT includes a base layer 104 formed on the collector layer 103, an emitter layer 105 formed on the base layer 104, and an emitter cap layer 106 formed on the emitter layer 105. The emitter layer 105 and the emitter cap layer 106 have a mesa shape.

The base layer 104 is formed of GaN. In this example, the base layer 104 is provided with a p-base layer 104a made of p-type GaN at a central part in the thickness direction. As is well known, although GaN has a certain limitation in p-type formation, it is desirable to form the p-base layer 104a from GaN into which p-type impurities are introduced at a high concentration within a possible range in consideration of crystal quality or the like. An upper base layer 104c on the upper side of the p-base layer 104a and a lower base layer 104b on the lower side are undoped or become a p-type with an impurity concentration lower than that of the p-base layer 104a. The lower base layer 104b can have a thickness of about 2 nm. The p-base layer 104a can have a thickness of about 5 nm. The upper base layer 104c can have a thickness of about 2 nm.

The emitter layer 105 is made of a nitride semiconductor containing Al. The emitter layer 105 can be made of AlGaN (Al_{0.25}Ga_{0.75}N). The thickness of the emitter layer 105 can be about 20 nm.

An emitter cap layer 106 is made of an n-type nitride semiconductor. The emitter cap layer 106 is a layer for forming an ohmic contact having a low contact resistance, and the n-type impurity concentration is set to a high concentration. For example, the emitter cap layer 106 can have an n-type impurity concentration of 5×10¹⁸ cm⁻³ or more. In this layer, it is also effective to increase the concentration of impurities and to narrow the band gap for ohmic contact with metal. Therefore, the emitter cap layer 106 may be made of InGaN or the like, for example, without being limited to GaN. The thickness of the emitter cap layer 106 can be about 100 nm.

Further, the sub-collector layer 102, the collector layer 103, the base layer 104, the emitter layer 105, and the emitter cap layer 106 can be formed on the substrate 101 in a state in which the principal surface is a group V polar plane.

The HBT includes an emitter electrode 11 formed on the emitter cap layer 106, a base electrode 112 formed on the base layer 104 lateral to the emitter layer 105 and ohmically connected to the base layer 104, and a collector electrode 113 connected to the sub-collector layer 102. The base electrode 112 can be formed in contact with the upper part of the base layer 104 around the emitter layer 105 formed in a mesa shape.

The HBT having the above-described structure according to the embodiment includes two-dimensional hole gases 121 formed in each of the base layer 104 in the vicinity of the interface between the base layer 104 and the emitter layer 105 and in the collector layer 103 in the vicinity of the interface between the collector layer 103 and the base layer 104.

The HBT according to an embodiment in which the two-dimensional hole gas 121 is formed will be described in more detail below.

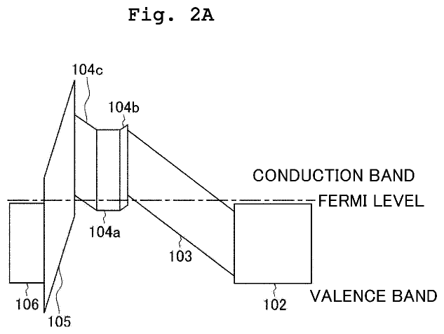

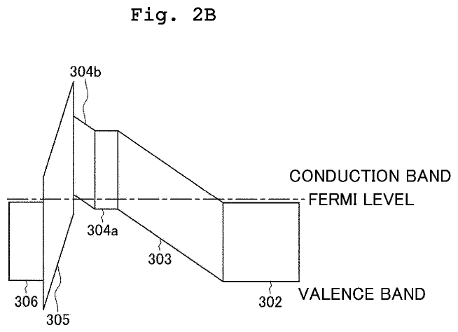

As shown in the band diagram of FIG. 2A, according to an HBT according to an embodiment in which the N polar plane is constituted as a principal plane orientation, bending of the band due to the effect of polarization is different compared with a case in which the HBT is made of a general group III polarity.

First, the two-dimensional hole gas 121 is generated by the influence of a polarization electric field caused by a hetero structure in each of an interface between the collector layer 103 and the base layer 104 (the lower base layer 104b) and an interface between the emitter layer 105 and the base layer 104 (the upper base layer 104c).

At the interface between the emitter layer 105 and the base layer 104 (the upper base layer 104c), the band is raised upward because the magnitude of polarization of each layer is different. In this state, since the p-base layer 104a exists in the central part (immediately under the upper base layer 104c) of the base layer 104, the energy of the valence band at the interface exceeds Fermi energy (Fermi level) and the two-dimensional hole gas 121 of high concentration is formed.

Next, attention is paid to the p-base layer 104a, the lower base layer 104b, and the collector layer 103. First, InGaN has a larger spontaneous polarization than GaN. Further, since the collector layer 103 made of InGaN exists between the p-base layer 104a and the sub-collector layer 102, spontaneous polarization acts in a direction for promoting an internal electric field of the collector layer 103. Further, the lower base layer 104b made of undoped GaN exists between the p-base layer 104a and the collector layer 103. Therefore, the band is raised upward even at the interface between the lower base layer 104b and the collector layer 103. As a result, the two-dimensional hole gas 121 having a high concentration is formed on the interface.

On the other hand, in the N polar plane GaN hetero-junction bipolar transistor of the related art, as shown in a band diagram of FIG. 2B, the collector layer 303 made of GaN is simply connected to the p-base layer 304a and the sub-collector layer 302. Since the p-base layer 304a, the collector layer 303, and the sub-collector layer 302 are all made of the same material (GaN in this case), an electric field due to a polarization difference between the materials is not generated, and only a p-i-n junction is simply formed.

As compared with a structure of the related art, since an interface is formed by the lower base layer 104b made of GaN and the collector layer 103 made of InGaN in embodiments of the present invention, as described above, a two-dimensional hole gas is generated by the effect of hetero-junction, and as a result, the hole concentration of the two-dimensional hole gas 121 formed in the collector layer 103 in the vicinity of the base layer can be set higher.

Next, the effects of embodiments of the present invention when manufacturing the device will be described in detail. In an HBT structure having an N polar plane as a principal plane orientation, a technique for increasing the concentration of the base layer by forming a two-dimensional hole gas at an interface between the emitter layer and the base layer is used. In such an emitter top structure, ohmic contacts between the metal electrode and the emitter contact layer, the base layer, and the sub-collector layer need to be formed from the upper surface side (front surface side) of the device.

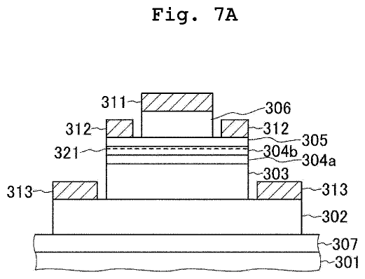

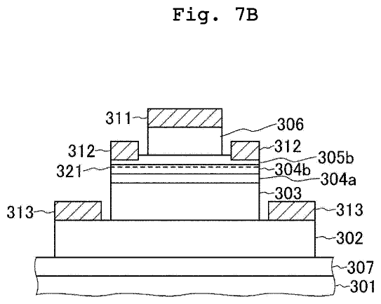

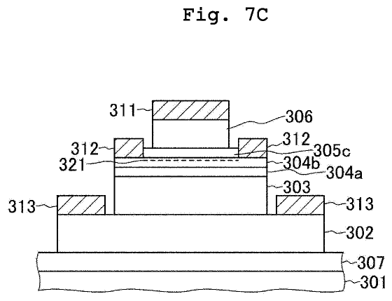

However, since the emitter layer made of AlGaN has a high resistance, when the base electrode is formed from immediately above the emitter, the ohmic contact resistance becomes high (FIG. 7A). In order to obtain a good ohmic contact with the base layer, it is necessary to partially remove the emitter layer immediately under the base electrode by etching (FIG. 7B). However, when the emitter layer is completely removed, the two-dimensional hole gas concentration is extremely reduced (eliminated) (FIG. 7C), and therefore, etching of the emitter layer for forming the base electrode requires very high controllability.

However, in embodiments of the present invention, even if the emitter layer 105 does not exist at all at the place where the base electrode 112 is formed, the two-dimensional hole gas 121 exists also at the interface between the collector layer 103 and the base layer 104 (the lower base layer 104b). Therefore, even if the emitter layer 105 at the position where the base electrode 112 is formed is completely removed and the base electrode 112 is formed in contact with the upper part of the base layer 104 (the upper base layer 104c), a decrease in the hole concentration of the base layer 104 in this region can be suppressed. As a result, good ohmic contact between the base layer 104 and the base electrode 112 can be realized.

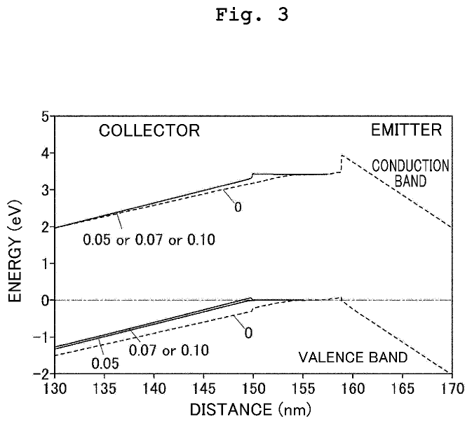

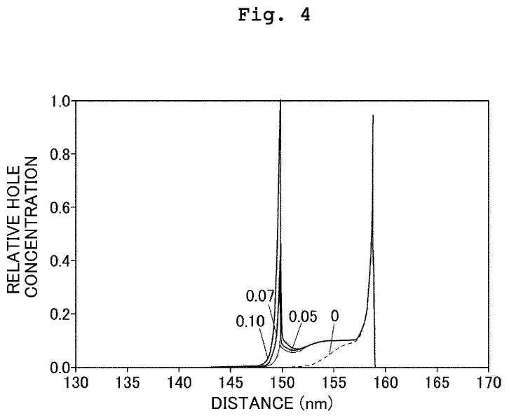

Next, the results obtained by performing band calculation and calculation of sheet carrier density in the HBT layer structure according to the above-described embodiment will be described with reference to FIGS. 3 and 4. The following parameters were used for the calculation.

The sub-collector layer 102 is made of n-type GaN having an impurity concentration of about 10¹⁹ cm⁻³, and the collector layer 103 is made of InGaN and has a thickness of 50 nm. In FIGS. 3 and 4, the numbers (0, 0.05, 0.07, and 0.10) shown in the drawings indicate the In composition of InGaN that forms the collector layer 103.

The lower base layer 104b is made of undoped GaN and has a thickness of 2 nm, the p-base layer 104a is made of p-type GaN having an impurity concentration of about 10¹⁹ cm⁻³ and has a thickness of 5 nm, and the upper base layer 104c is made of undoped GaN and has a thickness of 2 nm. Further, the emitter layer 105 is made of Al_{0.25}Ga_{0.75}N and has a thickness of 20 nm, and the emitter cap layer 106 is made of n-type GaN with an impurity concentration of about 10¹⁹ cm⁻³ and has a thickness of 100 nm.

Under the condition that the In composition of the collector layer 103 is 0, the influence of polarization caused by a hetero structure is not generated on the interface between the lower base layer 104b (base layer 104) and the collector layer 103 made of GaN, and the band of the interface is not raised. Therefore, as indicated by a dotted line in FIG. 4, no two-dimensional hole gas is generated, and the carrier density (hole density) at the interface is low.

When the In composition of the collector layer 103 is higher than 0.05, the band at the interface between the lower base layer 104b (base layer 104) and the collector layer 103 rises due to the influence of the polarization electric field caused by the hetero structure, and as shown in FIG. 3, the energy of the valence band edge becomes comparable to or higher than the Fermi level. As a result, as shown in FIG. 4, the high hole density is obtained when the In composition of the collector layer 103 is 0.05 or more.

By adjusting the above-mentioned layer structure (thickness, composition, doping concentration, etc.), the polarization effect can be obtained even with a lower In composition, and the high hole concentration can also be obtained. It is important that the collector layer 103 made of InGaN, the lower base layer 104b, and the p-base layer 104a are laminated in this order. In addition, the orientation of the polarity of the layer structure is important, and it is important that they are laminated in this order from the substrate side for N polarity, and they are laminated in the opposite order for group III polarity.

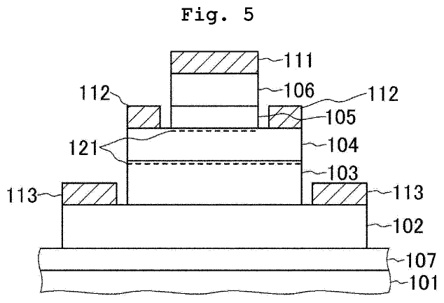

Although the configuration in which the p-base layer 104a is provided at the central part in the thickness direction of the base layer 104 is provided in the above description, this is not the necessary configuration. As shown in FIG. 5, the entire base layer 104 can be made of undoped GaN. In this configuration, the base layer 104 is made of undoped GaN and can be made to a thickness of about 4 nm. Other configurations are the same as those of the above-described embodiment, and description thereof will not be provided.

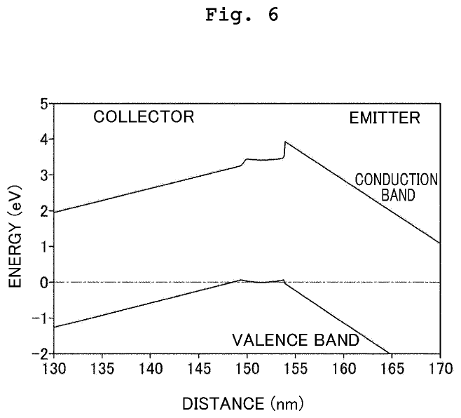

The results obtained by performing the band calculation and the sheet carrier density calculation in the HBT layer structure of the case of this configuration will be described with reference to FIG. 6. The following parameters were used for the calculation.

The sub-collector layer 102 is made of n-type GaN having an impurity concentration of about 10¹⁹ cm⁻³, the collector layer 103 is made of In_{0.1}Ga_{0.9}N and has a thickness of 50 nm, and the base layer 104 is made of undoped GaN and has a thickness of 4 nm. The emitter layer 105 is made of Al_{0.25}Ga_{0.75}N and has a thickness of 20 nm, and the emitter cap layer 106 is made of n-type GaN with an impurity concentration of about 10¹⁹ cm⁻³ and has a thickness of 100 nm.

In this structure, no p-base layer is introduced. Therefore, the structure is simply formed by laminating the emitter layer 105 made of undoped AlGaN, the base layer 104 made of undoped GaN, and the collector layer 103 made of undoped InGaN. Even with such a structure that does not use the p-type doping layer, a two-dimensional hole gas is generated in the collector layer 103 near the interface due to the influence of a polarization electric field caused by the hetero structure between the collector layer 103 and the base layer 104, and a high hole concentration can be obtained. In the hetero structure of the emitter layer 105 and the base layer 104, a two-dimensional hole gas is generated in the base layer 104 near the interface due to the influence of the polarization electric field caused by the hetero structure of the emitter layer 105 and the base layer 104.

It has been reported that GaN is a material which has a high ionization energy of a dopant and is difficult to increase a hole concentration, even if p-type doping is performed by Mg or the like, and that the dopant is inactivated by the influence of H used in a raw material or a carrier gas during growth. Due to these reasons, introduction of the p-type layer may be a significant restriction from the viewpoint of device process and crystal quality. However, since the present structure can achieve a high hole concentration in the base layer without using any p-type layer, an HBT structure can be achieved in a state of high crystal quality and high mobility, and further improvement of high frequency characteristics can be expected.

As described above, according to embodiments of the present invention, the base layer made of GaN is formed on the collector layer made of InGaN with the principal surface thereof being a group V polar plane, and the emitter layer made of a nitride semiconductor containing Al is formed on the base layer. As a result, two-dimensional hole gas is formed in each of the base layer near the interface between the base layer and the emitter layer and the collector layer near the interface between the collector layer and the base layer, and good ohmic contact between the base layer and the base electrode can be obtained in a GaN-based bipolar transistor structure having N polarity as a principal plane orientation.

Note that it is clear that the embodiments of the present invention are not limited to the embodiments described above and within the technical concept of the present invention and many modifications and combinations can be implemented by those skilled in the art.

1.-4. (canceled)

5. A hetero-junction bipolar transistor comprising:
a sub-collector layer disposed on a substrate and comprising a first n-type nitride semiconductor;
an n-type collector layer disposed on the sub-collector layer and comprising InGaN;
a base layer disposed on the collector layer and comprising GaN;
an emitter layer having a mesa shape disposed on the base layer and comprising a nitride semiconductor containing Al;
an emitter cap layer disposed on the emitter layer and comprising a second n-type nitride semiconductor;
an emitter electrode disposed on the emitter cap layer;
a base electrode disposed on the base layer beside the emitter layer and ohmically connected to the base layer;
a collector electrode connected to the sub-collector layer; and
a two-dimensional hole gas disposed in the base layer near a first interface between the base layer and the emitter layer and disposed in the collector layer near a second interface between the collector layer and the base layer, wherein the sub-collector layer, the collector layer, the base layer, the emitter layer, and the emitter cap layer are disposed on the substrate with principal surfaces being Group V polar planes.

6. The hetero-junction bipolar transistor according to claim 5, wherein the n-type collector layer comprises InGaN with an In composition of 0.05 or more.

7. The hetero-junction bipolar transistor according to claim 5, wherein the base layer comprises a p-base layer comprising p-type GaN in a central part in a thickness direction.

8. The hetero-junction bipolar transistor according to claim 7, wherein the base layer further comprises an upper base layer on an upper side of the p-base layer and a lower base layer on a lower side of the p-base layer, and wherein the upper base layer and the lower base layer are undoped or are a p-type with an impurity concentration lower than that of the p-base layer.

9. The hetero-junction bipolar transistor according to claim 8, wherein the n-type collector layer comprises InGaN with an In composition of 0.05 or more.

10. The hetero-junction bipolar transistor according to claim 7, wherein the n-type collector layer comprises InGaN with an In composition of 0.05 or more.

11. A method of manufacturing a hetero-junction bipolar transistor, the method comprising:
forming a sub-collector layer on a substrate, the sub-collector layer comprising a first n-type nitride semiconductor;
forming an n-type collector layer on the sub-collector layer, the n-type collector layer comprising InGaN;
forming a base layer on the collector layer, the base layer comprising GaN;
forming an emitter layer having a mesa shape on the base layer, the emitter layer comprising a nitride semiconductor containing Al;
forming an emitter cap layer on the emitter layer, the emitter cap layer comprising a second n-type nitride semiconductor;
forming an emitter electrode on the emitter cap layer;
forming a base electrode on the base layer lateral to the emitter layer and ohmically connected to the base layer;
forming a collector electrode connected to the sub-collector layer; and
forming a two-dimensional hole gas in the base layer near a first interface between the base layer and the emitter layer and in the collector layer near a second interface between the collector layer and the base layer, wherein the sub-collector layer, the collector layer, the base layer, the emitter layer, and the emitter cap layer are formed on the substrate with principal surfaces being Group V polar planes.

12. The method according to claim 11, wherein the n-type collector layer comprises InGaN with an In composition of 0.05 or more.

13. The method according to claim 11, wherein forming the base layer comprises forming a p-base layer comprising p-type GaN in a central part in a thickness direction.

14. The method according to claim 13, wherein forming the base layer further comprises forming an upper base layer on an upper side of the p-base layer and a lower base layer on a lower side of the p-base layer, and wherein the upper base layer and the lower base layer are undoped or are a p-type with an impurity concentration lower than that of the p-base layer.

15. The method according to claim 14, wherein the n-type collector layer comprises InGaN with an In composition of 0.05 or more.

16. The method according to claim 13, wherein the n-type collector layer comprises InGaN with an In composition of 0.05 or more.
